(19) United States
(12) Patent Application Publication
(10) Pub. No.: US 2017/0243797 A1
(43) Pub. Date: Aug. 24, 2017

(54) DISPLAY DRIVING DEVICE

(71) Applicant: SILICON WORKS CO., LTD., Daejeon-si (KR)

(72) Inventors: Young Bok KIM, Daejeon-si (KR); Dong Hun Lee, Seoul (KR); Hyun Kyu Jeon, Daejeon-si (KR); Joon Ho Na, Daejeon-si (KR)

(73) Assignee: SILICON WORKS CO., LTD., Daejeon-si (KR)

(21) Appl. No.: 15/439,178

(22) Filed: Feb. 22, 2017

(30) Foreign Application Priority Data
Feb. 24, 2016 (KR) 10-2016-0021962

(51) Int. Cl. H01L 21/66; H01L 23/00

(52) U.S. Cl. CPC H01L 22/34; H01L 24/48; H01L 2224/48227; H01L 2924/30101

(57) ABSTRACT

Disclosed is a display driving device including a bonding resistance measurement circuit. The display driving device may include: first and second pads bonded to a pad of a display panel through a wire and configured to provide bonding resistance; and a bonding resistance measurement circuit configured to measure the bonding resistance by comparing an input voltage applied to the bonding resistance through the first pad to one or more preset reference voltages.

### BACKGROUND

1. Technical Field

The present disclosure relates to a display driving device, and more particularly, to a technique for measuring bonding resistance.

2. Related Art

In general, a display driving device is manufactured with an integrated circuit (IC), and the IC is mounted on a display panel.

The mounting method may be divided into COG (Chip On Glass), TCP (Tape Carrier Package) and COF (Chi On Film). Among the mounting methods, the COG method has a simpler structure than the TCP method and the COF method. Thus, the COG method is widely used.

According to the COG method, a display driving device is bonded on a display panel through a wire. At this time, since the bonding resistance of the wire may have an influence on power, the bonding resistance needs to be set as low as possible.

Therefore, it is necessary to measure whether the IC is normally bonded or how much the bonding resistance is.

According to the related art, an external measuring device is connected to a pad of a display panel, in order to measure bonding resistance. In this method, resistance from the display panel to the measuring device and an error of the measuring device are added. Thus, an accurate bonding resistance value cannot be acquired.

Therefore, there is a demand for a technique for accurately measuring the magnitude of bonding resistance that has a large influence on the operating ability of the display driving device.

### SUMMARY

Various embodiments are directed to a display driving device including a bonding resistance measurement circuit capable of accurately measuring bonding resistance.

Also, various embodiments are directed to a display driving device capable of checking whether bonding was normally conducted, through measured bonding resistance.

In an embodiment, a display driving device may include: first and second pads bonded to a pad of a display panel, and configured to provide bonding resistance; and a bonding resistance measurement circuit configured to measure the bonding resistance by comparing an input voltage applied to the bonding resistance through the first pad to one or more preset reference voltages.

In an embodiment, a display driving device may include: first and second pads bonded to a pad of a display panel, and configured to provide bonding resistance; a first resistor configured to transmit an input voltage dropping a supply voltage to the first pad; a reference voltage generation unit configured to generate a first reference voltage and a second reference voltage from the supply voltage, the second reference voltage being larger than the first reference voltage; and a bonding resistance determination unit configured to determine the range of the bonding resistance according to a magnitude relation between the input voltage and the first reference voltage and a magnitude relation between the input voltage and the second reference voltage.

According to the present embodiments, since the bonding resistance measurement circuit is embedded in the display driving device, the bonding resistance between the display panel and the display driving device can be accurately measured.

Furthermore, the display driving device having the bonding resistance measurement circuit embedded therein can be used to check whether bonding was normally conducted, through measured bonding resistance.

### BRIEF DESCRIPTION OF THE DRAWINGS

FIG. 1 is a block diagram illustrating a pad configuration of a display driving device including a bonding resistance measurement circuit according to an embodiment of the present invention.

FIG. 2 is a circuit diagram of the bonding resistance measurement circuit according to the embodiment of the present invention.

FIG. 3 is a flowchart for describing an operation of the bonding resistance measurement circuit of FIG. 2.

### DETAILED DESCRIPTION

Hereafter, embodiments of the present invention will be described in detail with reference to the accompanying drawings. The terms used in the present specification and claims are not limited to typical dictionary definitions, but must be interpreted into meanings and concepts which coincide with the technical idea of the present invention.

Embodiments described in the present specification and configurations illustrated in the drawings are preferred embodiments of the present invention, and do not represent the entire technical idea of the present invention. Thus, various equivalents and modifications capable of replacing the embodiments and configurations may be provided at the point of time that the present application is filed.

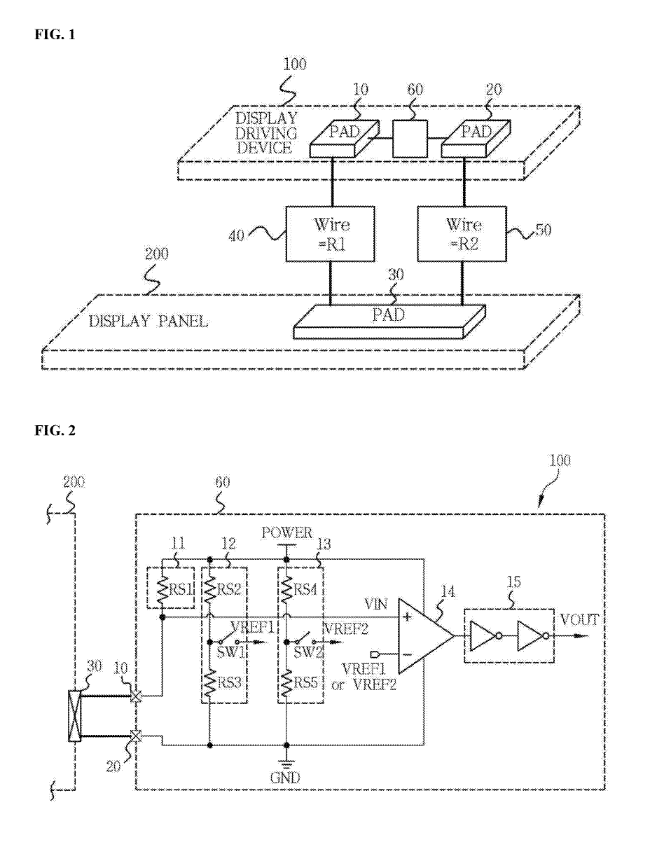

FIG. 1 is a circuit diagram illustrating a pad configuration of a bonding resistance measurement circuit according to an embodiment of the present invention.

Referring to FIG. 1, a display driving device 100 according to an embodiment of the present invention includes two pads 10 and 20 and a bonding resistance measurement circuit 60. The two pads 10 and 20 are bonded to a pad 30 of a display panel 200 through wires 40 and 50, and the bonding resistance measurement circuit 60 is installed in the display driving device 100 in order to measure bonding resistance.

The bonding resistance measurement circuit 60 measures bonding resistance R1+R2 from the pad 10 to the pad 20.

According to the present embodiment, a supply voltage POWER is applied to the pad 10 and a ground voltage GND is applied to the other pad 20, in order to measure the bonding resistance. The supply voltage POWER may include VDD or VCC, and is applied to the pad 10 through a resistor.

The bonding resistance measurement circuit 60 according to the present embodiment measures the range of the bonding resistance R1+R2 using a voltage between the pad 10 and the pad 20. The bonding resistance measurement circuit 60 has the following configuration.

FIG. 2 is a circuit diagram of the bonding resistance measurement circuit according to the embodiment of the present invention.

Referring to FIG. 2, the bonding resistance measurement circuit 60 according to the embodiment of the present invention includes a voltage dropping unit 11, reference voltage generation units 12 and 13, a comparison unit 14 and a buffer unit 15.

The voltage dropping unit 11 may include a resistor RS1, and transmit an input voltage VIN dropped from the supply voltage POWER to the first pad 10.

The reference voltage generation unit 12 includes resistors RS2 and RS3. Furthermore, the reference voltage generation unit 12 includes a switch SW1 configured to transmit a reference voltage VREF1 to the comparison unit 14, the reference voltage VREF1 being divided from the supply voltage POWER by the resistors RS1 and RS3. The resistors RS2 and RS3 are connected in series between the supply voltage POWER and the ground voltage GND, and the voltage divided by the resistors RS2 and RS3 is provided as the reference voltage VREF1. The switch SW1 is turned on when bonding resistance measurement is started, and turned off when the input voltage VIN is larger than the reference voltage VREF1.

The reference voltage generation unit 13 includes resistors RS4 and RS5. Furthermore, the reference voltage generation unit 13 includes a switch SW2 configured to transmit a reference voltage VREF2 to the comparison unit 14, the reference voltage VREF2 being divided from the supply voltage POWER by the resistors RS4 and RS5. The resistors RS4 and RS5 are connected in series between the supply voltage POWER and the ground voltage GND, and the voltage divided by the resistors RS4 and RS5 is provided as the reference voltage VREF2. The switch SW2 is turned on when the input voltage VIN is larger than the reference voltage VREF1.

In FIG. 2, the first resistor RS1, the second resistor RS2 and the fourth resistor RS4 have the same resistance value, and the third resistor RS3 has a smaller resistance value than the fifth resistor RS5.

The comparison unit 14 compares the input voltage VIN and the reference voltage VREF1 when the switch SW1 is turned on, or compares the input voltage VIN and the reference voltage VREF2 when the switch SW2 is turned on, and outputs a comparison signal corresponding to the comparison result. The buffer unit 15 includes inverters, buffers the comparison signal, and then outputs an output voltage VOUT.

The comparison unit 14 determines the range of the bonding resistance R1+R2, depending on which one of the input voltage VIN and the reference voltage VREF1 is higher than the other voltage. The input voltage VIN is a voltage divided from the supply voltage POWER by the resistor RS1 and the bonding resistance R1+R2, and the reference voltage VREF1 is a voltage divided from the supply voltage POWER by the resistors RS2 and RS3.

Furthermore, the comparison unit 14 determines the range of the bonding resistance R1+R2, depending on which one of the input voltage VIN and the reference voltage VREF2 is lower than the other voltage. The reference voltage VREF2 is a voltage divided from the supply voltage POWER by the resistors RS4 and RS5.

For example, the comparison unit 14 according to the present embodiment determines that the range of the bonding resistance R1+R2 is between zero and the resistance of the resistor RS3 when the input voltage VIN is smaller than the reference voltage VREF1, determines that the range of the bonding resistance R1+R2 is between the resistance of the resistor RS3 and the resistance of the resistor RS5 when the input voltage VIN is larger than the reference voltage VREF1 and smaller than the reference voltage VREF2, and determines that the range of the bonding resistance R1+R2 is larger than the resistance of the resistor RS5 when the input voltage VIN is larger than the reference voltage VREF2.

As such, the comparison unit 14 serves as a bonding resistance determination unit which determines the range of the bonding resistance according to the magnitude relation between the input voltage VIN and the reference voltage VREF1 or between the input voltage VIN and the reference voltage VREF2. The resistors RS3 and RS5 are internal passive resistance elements for one-to-one comparison to the bonding resistance R1+R2, and the resistors RS1, RS2 and RS4 are passive resistance elements which are operated in the voltage input range of the comparison unit 14.

The switches SW1 and SW2 are controlled by a controller (not illustrated). When the bonding resistance measurement is started, the controller turns on the switch SW1 to transmit the reference voltage VREF1 to the comparison unit 14. When a comparison result of the comparison unit 14 indicates that the input voltage VIN is larger than the reference voltage VREF1, the controller turns on the switch SW2 to transmit the reference voltage VREF2 to the comparison unit 14. At this time, when the switch SW1 is turned on, the switch SW2 is turned off, and when the switch SW2 is turned on, the switch SW1 is turned off.

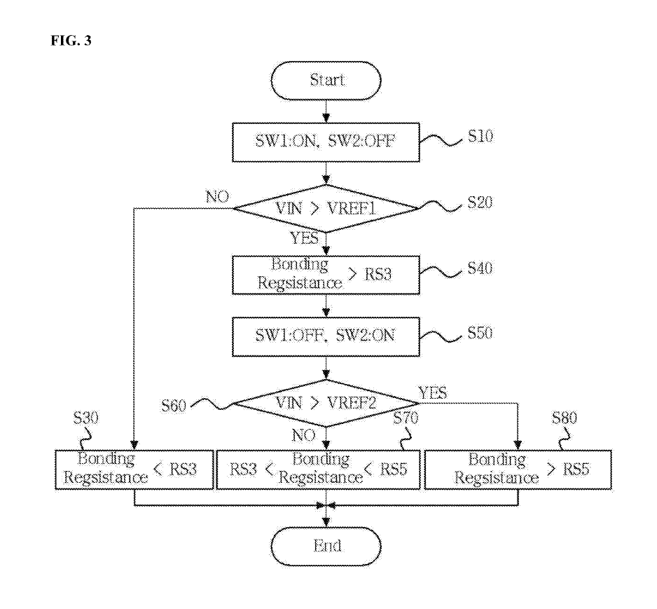

FIG. 3 is a flowchart for describing the operation of the bonding resistance measurement circuit of FIG. 2.

Referring to FIG. 3, when bonding resistance measurement is started, the bonding resistance measurement circuit 60 turns on the switch SW1 and turns off the switch SW2, at step S10.

The bonding resistance measurement circuit 60 compares the input voltage VIN to the reference voltage VREF1 transmitted through the switch SW1 at step S20.

When the input voltage VIN is smaller than the reference voltage VREF1, the bonding resistance measurement circuit 60 determines that the bonding resistance R1+R2 is smaller than the resistance value of the resistor RS3, at step S30.

On the other hand, when the input voltage VIN is larger than the reference voltage VREF1, the bonding resistance measurement circuit 60 determines that the bonding resistance R1+R2 is larger than the resistance value of the resistor RS3, at step S40. Then, the bonding resistance measurement circuit 60 turns off the switch SW1 and turns on the switch SW2, at step S50.

Then, the bonding resistance measurement circuit 60 compares the input voltage VIN to the reference voltage VREF2 transmitted through the switch SW2 at step S60.

When the input voltage VIN is smaller than the reference voltage VREF2, the bonding resistance measurement circuit 60 determines that the bonding resistance R1+R2 is larger than the resistance value of the resistor RS3 and smaller than the resistance value of the resistor RS5, at step S70.

When the input voltage VIN is larger than the reference voltage VREF2, the bonding resistance measurement circuit 60 determines that the bonding resistance R1+R2 is larger than the resistance value of the resistor RS5, at step S80.

As such, the bonding resistance measurement circuit 60 determines that the range of the bonding resistance R1+R2 is between zero and the resistance of the resistor RS3 when the input voltage VIN is smaller than the reference voltage VREF1, determines that the range of the bonding resistance R1+R2 is between the resistance of the resistor RS3 and the resistance of the resistor RS5 when the input voltage VIN is larger than the reference voltage VREF1 and smaller than the reference voltage VREF2, and determines that the range of the bonding resistance R1+R2 is larger than the resistance of the resistor RS5 when the input voltage VIN is larger than the reference voltage VREF2.

If the design area and switch signals are allowed, switches may be added to more precisely determine the magnitude of the bonding resistance.

In the COG technology, the bonding resistance of a wire has a large influence on the operating ability of the chip. Thus, it is very important to determine the magnitude of the bonding resistance. For example, when the bonding was normally conducted, the wire has a bonding resistance of several ohms to tens of ohms (Q). However, when the bonding was not normally conducted, the wire may have a bonding resistance of several hundreds of ohms to several kill-ohms (Q).

Since the bonding resistance measurement circuit according to the present embodiment can determine the magnitude range of the bonding resistance, the bonding resistance measurement circuit can be utilized as a circuit capable of checking whether the display driving device 100 was normally bonded to the display panel 200.

While various embodiments have been described above, it will be understood to those skilled in the art that the embodiments described are by way of example only. Accordingly, the disclosure described herein should not be limited based on the described embodiments.

What is claimed is:

1. A display driving device comprising:
first and second pads bonded to a pad of a display panel, and configured to provide bonding resistance; and
a bonding resistance measurement circuit configured to measure the bonding resistance by comparing an input voltage applied to the bonding resistance through the first pad to one or more preset reference voltages.

2. The display driving device of claim 1, wherein the bonding resistance measurement circuit generates the reference voltages having different magnitudes, compares the input voltage to the reference voltages one to one, and determines the range of the bonding resistance according to the magnitude relations between the input voltage and the reference voltages.

3. The display driving device of claim 1, wherein the bonding resistance measurement circuit comprises:
a first resistor configured to transmit the input voltage dropping a supply voltage to the first pad;
a first reference voltage generation unit configured to generate a first reference voltage from the supply voltage;
a second reference voltage generation unit configured to generate a second reference voltage from the supply voltage, the second reference voltage being larger than the first reference voltage; and
a comparison unit configured to compare the input voltage to the first reference voltage or compare the input voltage to the second reference voltage, and output a comparison signal corresponding to the comparison result.

4. The display driving device of claim 3, wherein the first reference voltage generation unit comprises second and third resistors between the supply voltage and the second pad, and comprises a first switch configured to transmit a voltage divided from the supply voltage by the second and third resistors as the first reference voltage to the comparator, and
the second reference voltage generation unit comprises fourth and fifth resistors between the supply voltage and the second pad, and comprises a second switch configured to transmit a voltage divided from the supply voltage by the fourth and fifth resistors as the second reference voltage to the comparator.

5. The display driving device of claim 4, wherein the first resistor, the second resistor and the fourth resistor have the same resistance value, and the third resistor has a smaller resistance value than the fifth resistor.

6. The display driving device of claim 5, wherein the bonding resistance measurement circuit determines that the range of the bonding resistance is between zero and the resistance of the third resistor when the input voltage is smaller than the first reference voltage, determines that the range of the bonding resistance is between the resistance of the third resistor and the resistance of the fifth resistor when the input voltage is larger than the first reference voltage and smaller than the second reference voltage, and determines that the range of the bonding resistance is larger than the resistance of the fifth resistor when the input voltage is larger than the second reference voltage.

7. The display driving device of claim 4, wherein the first switch is turned on when bonding resistance measurement is started, and turned off when the input voltage is larger than the first reference voltage, and
the second switch is turned on when the input voltage is larger than the first reference voltage.

8. The display driving device of claim 3, wherein the bonding resistance measurement circuit further comprises a buffer unit configured to buffer the comparison signal.

9. A display driving device comprising:
first and second pads bonded to a pad of a display panel, and configured to provide bonding resistance;
a first resistor configured to transmit an input voltage dropping a supply voltage to the first pad;
a reference voltage generation unit configured to generate a first reference voltage and a second reference voltage from the supply voltage, the second reference voltage being larger than the first reference voltage; and
a bonding resistance determination unit configured to determine the range of the bonding resistance according to a magnitude relation between the input voltage and the first reference voltage and a magnitude relation between the input voltage and the second reference voltage.

10. The display driving device of claim 9, wherein the reference voltage generation unit comprises:
second and third resistors configured to provide first voltage divided from the supply voltage between the supply voltage and the second pad as the first reference voltage;
a first switch configured to transmit the first reference voltage to the bonding resistance determination unit;
fourth and fifth resistors configured to provide second voltage divided from the supply voltage between the supply voltage and the second pad as the second reference voltage; and
a second switch configured to transmit the second reference voltage to the bonding resistance determination unit.

11. The display driving device of claim 10, wherein the first resistor, the second resistor and the fourth resistor have the same resistance value, and the third resistor has a smaller resistance value than the fifth resistor.

12. The display driving device of claim 11, wherein the bonding resistance determination unit determines that the range of the bonding resistance is between zero and the resistance of the third resistor when the input voltage is smaller than the first reference voltage, determines that the range of the bonding resistance is between the resistance of the third resistor and the resistance of the fifth resistor when the input voltage is larger than the first reference voltage and smaller than the second reference voltage, and determines that the range of the bonding resistance is larger than the resistance of the fifth resistor when the input voltage is larger than the second reference voltage.

13. The display driving device of claim 10, wherein the bonding resistance determination unit comprises:
a comparison unit configured to compare the input voltage to the first reference voltage or compare the input voltage to the second reference voltage, and output a comparison signal corresponding to the comparison result; and
a buffer unit configured to buffer the comparison signal.
